(19) United States
(12) Patent Application Publication
(10) Pub. No.: US 2006/0160283 A1
(43) Pub. Date: Jul. 20, 2006

(54) Method of fabricating a liquid crystal display device

(75) Inventor: Chin-Kuo Ting, Gueishan Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Quanta Display Inc.

(21) Appl. No.: 11/130,305

(22) Filed: May 16, 2005

(30) Foreign Application Priority Data
Jan. 19, 2005 (TW) 94101527

(51) Int. Cl. H01L 21/84

(52) U.S. Cl. 438/151; 438/163; 438/525; 438/527

(57) ABSTRACT

A method of fabricating a liquid crystal display device comprises the following steps. A first N-type LDD (Lightly Doped Drain) and a second N-type LDD are formed in a semiconductor layer by tilted ion implantation with a gate electrode serving as a mask. The two N-type LDDs are adjacent to source/drain regions, respectively. In addition, a third P-type LDD and a fourth P-type LDD are formed in a semiconductor layer by tilted ion implantation with a gate electrode serving as a mask as well. The two P-type LDDs are adjacent to the source/drain regions and the two N-type LDDs, respectively.

### BACKGROUND

The present invention relates to a method of fabricating a liquid crystal display device, and more particularly to a method of fabricating a liquid crystal display device having lightly doped drains (LDDs).

To increase the aperture ratio of a low temperature polysilicon liquid crystal display device, the channel between the source/drain electrodes must be shortened. When the channel is shortened, short channel effect occurs. Hot electron effect also occurs when the device is driven by voltage.

With the short channel, depletion regions between the source/drain electrodes narrow when voltage is applied to the device. Meanwhile, leakage current between the source/drain electrodes occurs, and punch-through effect intensifies. The electronic properties of a low temperature poly silicon liquid crystal display device are thus affected and the device may be unreliable.

Additionally, in a typical process of fabricating a lightly doped drain, the doping mask comprises a material of a photoresist layer. The process includes the steps of coating, exposure, and removal of photoresist layer.

In another process, spacers are formed, serving as a doping mask. The process includes deposition of a silicon oxide, dry etching, and formation of the spacers.

These steps complicate the processes and increase costs.

Accordingly, a more simplified process of fabricating a liquid crystal display device and a low-cost liquid crystal display device having lightly doped drains are needed.

### SUMMARY

To solve problems such as hot electron effect, leakage current problem, and punch-through effect, methods of the present invention are provided.

An object of the present invention is to provide a simplified process of fabricating a liquid crystal display device and a low-cost liquid crystal display device having lightly doped drains.

Another object of the present invention is to provide a process of fabricating a liquid crystal display device having N-type lightly doped drains.

It is another object of the present invention to provide a process of fabricating a liquid crystal display device having P-type lightly doped drains.

In accordance with an aspect of the present invention, a method of fabricating a liquid crystal display device is provided. Source/drain electrodes are formed by ion implantation, respectively, utilizing a gate electrode serving as a mask directly. Additionally, N-type lightly doped drains and P-type lightly doped drains are formed by tilted ion implantation, respectively. By changing the implantation angles and properly selecting doping energy and dosage, the location of lightly doped drains is changed. For example, a buried LDD may be formed in this manner.

A detailed description is given in the following embodiments with reference to the accompanying drawings.

### DESCRIPTION OF THE DRAWINGS

The invention can be more fully understood by reading the subsequent detailed description and examples with references made to the accompanying drawings, wherein:

FIGS. 1A to 1E are cross-sectional views of a method of fabricating a liquid crystal display device having N-type LDDs according to an embodiment of the present invention.

FIGS. 2A to 2E are cross-sectional views of a method of fabricating a liquid crystal display device having N-type LDDs according to another embodiment of the present invention.

FIGS. 3A to 3E are cross-sectional views of a method of fabricating a liquid crystal display device having N-type LDDs according to another embodiment of the present invention.

FIGS. 4A to 4E are cross-sectional views of a method of fabricating a liquid crystal display device having N-type LDDs according to another embodiment of the present invention.

FIGS. 5A to 5G are cross-sectional views of a method of fabricating a liquid crystal display device having P-type LDDs according to an embodiment of the present invention.

FIGS. 6A to 6G are cross-sectional views of a method of fabricating a liquid crystal display device having P-type LDDs according to another embodiment of the present invention.

FIGS. 7A to 7G are cross-sectional views of a method of fabricating a liquid crystal display device having P-type LDDs according to another embodiment of the present invention.

FIGS. 8A to 8G are cross-sectional views of a method of fabricating a liquid crystal display device having P-type LDDs according to another embodiment of the present invention.

### DETAILED DESCRIPTION

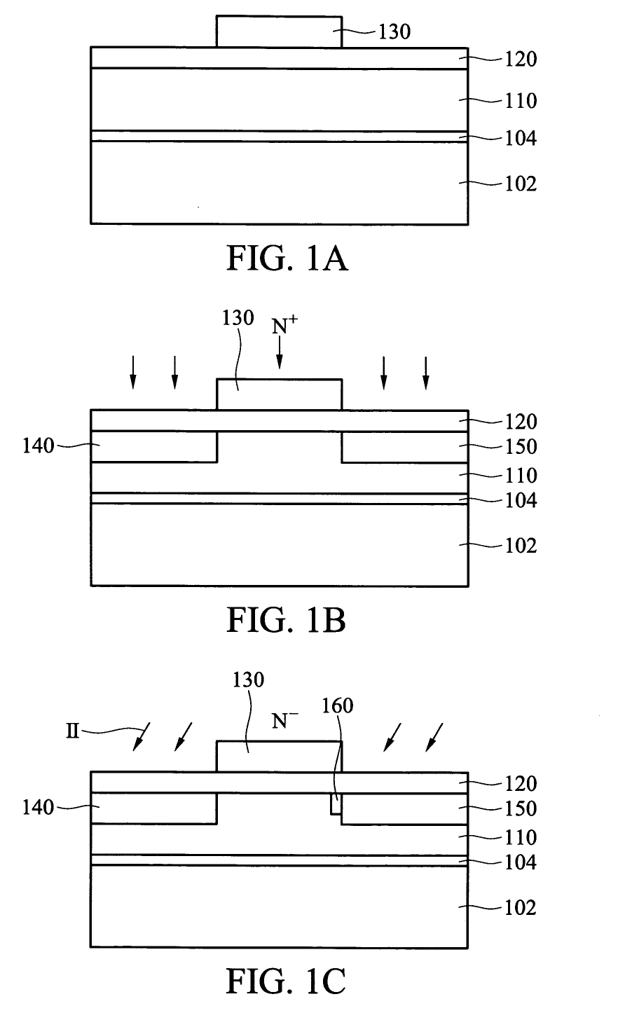

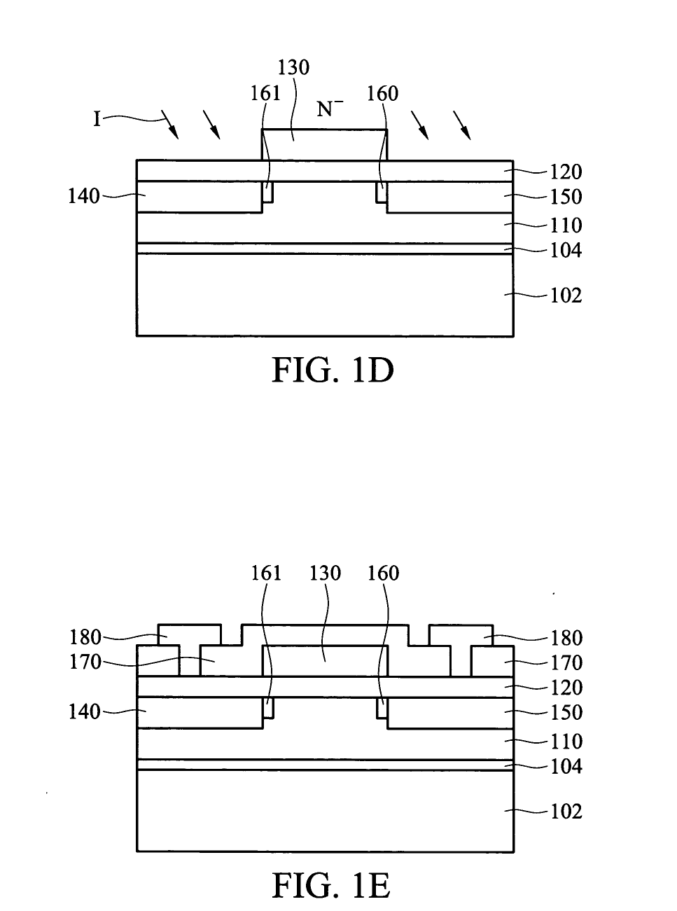

FIGS. 1A to 1E are cross-sectional views of a method of fabricating a liquid crystal display device according to an embodiment of the present invention. The method comprises the following steps.

As shown in FIG. 1A, a substrate 102 is provided followed by formation of a buffer layer 104 on the surface thereof. A semiconductor layer 110 is formed on the buffer layer 104 and a gate insulator layer 120 is formed on the semiconductor layer 110. Subsequently, a gate electrode 130 is formed on the gate insulator layer 120.

As shown in FIG. 1B, with the gate electrode 130 serving as a mask, an N-type dopant is implanted into the semiconductor layer 110 to form source/drain 140/150 regions by an ion implantation. The N-type dopant may comprise As, P, AsHₓ, or PHₓ. The N-type dopant is implanted into the semiconductor layer 110 substantially perpendicular to the surface of the substrate 102 at energy from 10 to 20 keV at dosage from 1*10¹⁵ to 5*10¹⁵ ions/cm².

As shown in FIGS. 1C and 1D, with the gate electrode 130 serving as a mask, an N-type dopant is implanted into the semiconductor layer 110 by two ion implantations, respectively, to form N-type lightly doped regions partially overlapping the source/drain 140/150 regions. Two N-type LDDs 160 and 161 are formed just below the gate insulator layer 120. The ion implantations are performed at energy from 10 to 50 keV at dosage from 5*10¹² to 1*10¹⁴ ions/cm². The N-type dopant is implanted into the semiconductor layer 110 at angle II and angle I deviating from a normal line of the substrate 102 by between 40 and 80°, respectively. The N-type dopant may comprise As, P, AsHₓ, or PHₓ.

As shown in FIG. 1E, an interlayer dielectric layer 170 is formed on the gate electrode 130 and the surface of the substrate 102. A conductive line 180 is formed in the interlayer dielectric layer 170, contacting the source/drain 140/150 regions.

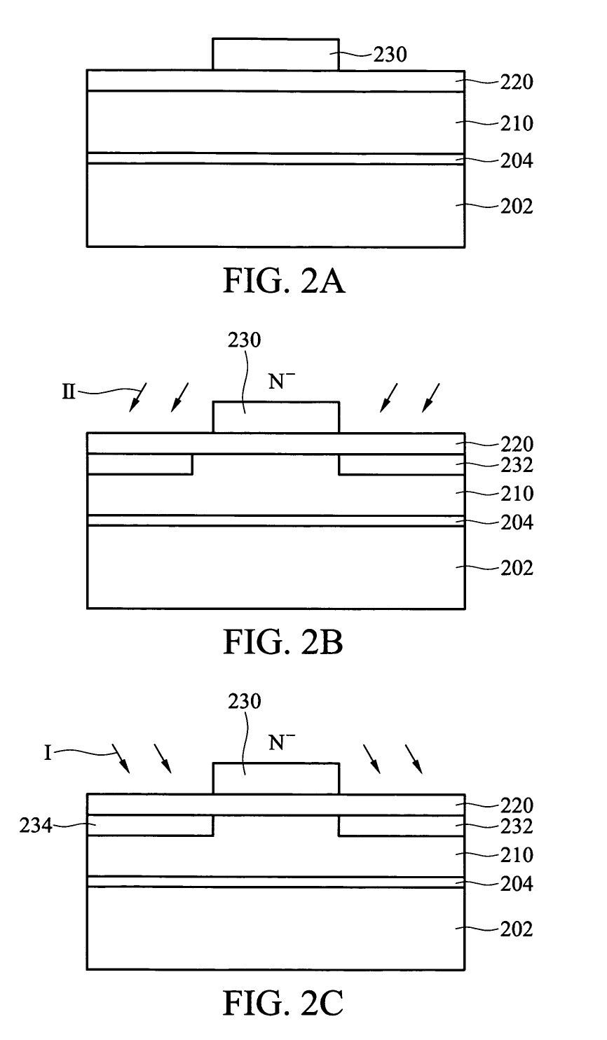

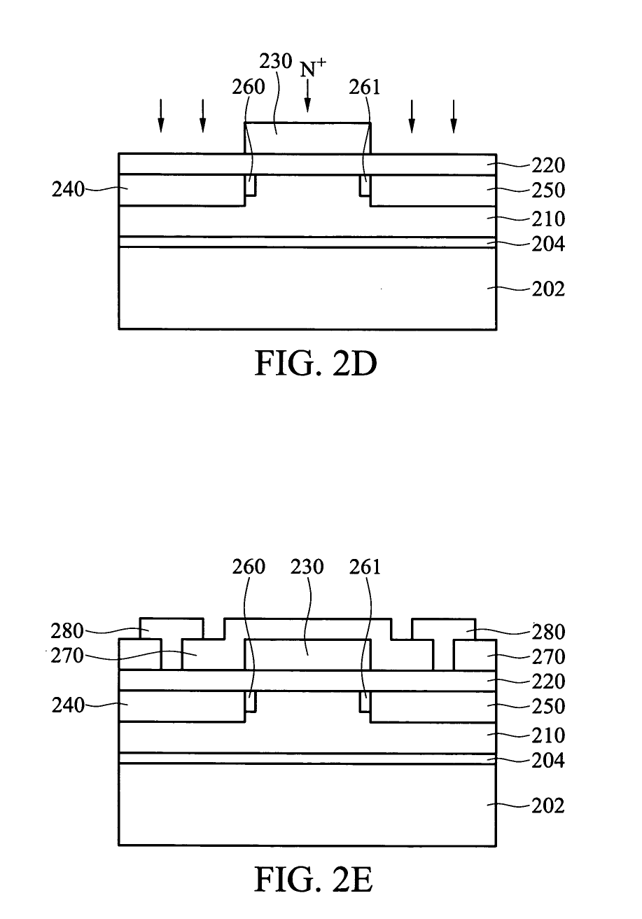

FIGS. 2A to 2E are cross-sectional views of a method of fabricating a liquid crystal display device according to another embodiment of the present invention. The method comprises the following steps.

As shown in FIG. 2A, a substrate 202 is provided followed by formation of a buffer layer 204 on the surface thereof. A semiconductor layer 210 is formed on the buffer layer 204 and a gate insulator layer 220 is formed on the semiconductor layer 210. Subsequently, a gate electrode 230 is formed on the gate insulator layer 220.

As shown in FIGS. 2B and 2C, with the gate electrode 230 serving as a mask, an N-type dopant is implanted into the semiconductor layer 210 by two ion implantations, respectively, to form N-type lightly doped regions 232 and 234. The ion implantations are performed at energy from 10 to 50 keV at dosage from 5*10¹² to 1*10¹⁴ ions/cm². The N-type dopant is implanted into the semiconductor layer 210 at angle II and angle I deviating from a normal line of the substrate 202 by between 40 and 80°, respectively. The N-type dopants may comprise As, P, AsHₓ, or PHₓ.

As shown in FIG. 2D, with the gate electrode 230 serving as a mask, an N-type dopant is implanted into the semiconductor layer 210 by an ion implantation, forming source/drain 240/250 regions partially overlapping the N-type lightly doped regions 232 and 234. Two N-type LDDs 260 and 261 are formed just below the gate insulator layer 220. The N-type dopant may comprise As, P, AsHₓ, or PHₓ. The N-type dopant is implanted into the semiconductor layer 210 substantially perpendicular to the surface of the substrate 202 at energy from 10 to 20 keV at dosage from 1*10¹⁵ to 5*10¹⁵ ions/cm².

As shown in FIG. 2E, an interlayer dielectric layer 270 is formed on the gate electrode 230 and the surface of the substrate 202. A conductive line 280 is formed in the interlayer dielectric layer 270, contacting the source/drain 240/250 regions.

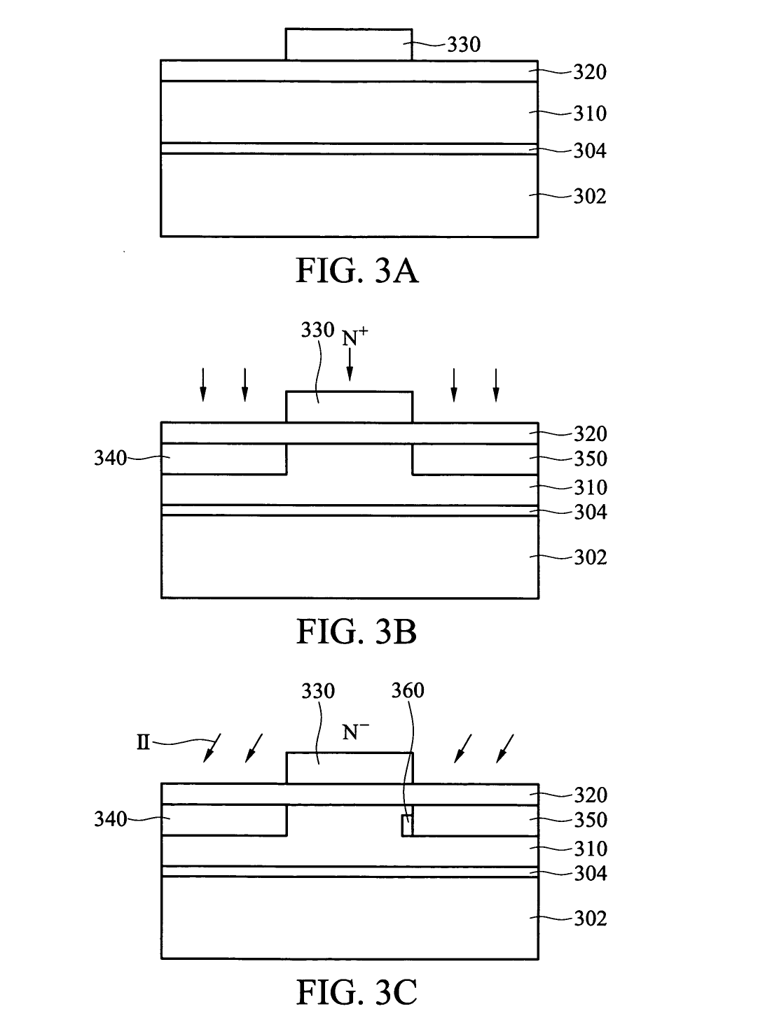

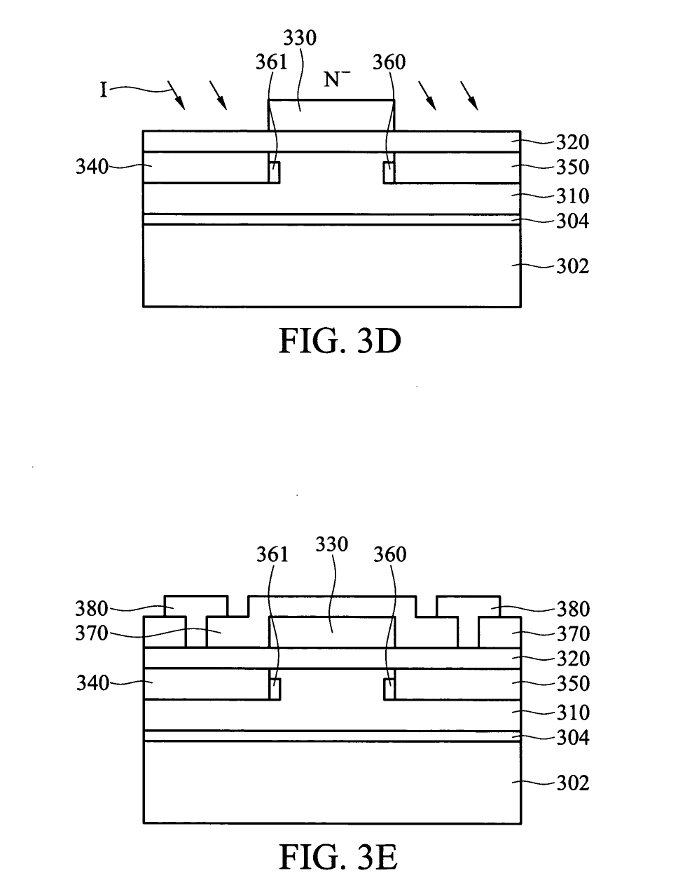

FIGS. 3A to 3E are cross-sectional views of a method of fabricating a liquid crystal display device according to another embodiment of the present invention. The method comprises the following steps.

As shown in FIG. 3A, a substrate 302 is provided followed by formation of a buffer layer 304 on the surface thereof. A semiconductor layer 310 is formed on the buffer layer 304 and a gate insulator layer 320 is formed on the semiconductor layer 310. Subsequently, a gate electrode 330 is formed on the gate insulator layer 320.

As shown in FIG. 3B, with the gate electrode 330 serving as a mask, an N-type dopant is implanted into the semiconductor layer 310 by an ion implantation, forming source/drain 340/350 regions. The N-type dopant may comprise As, P, AsHₓ, or PHₓ. The N-type dopant is implanted into the semiconductor layer 310 substantially perpendicular to the surface of the substrate 302 at energy from 10 to 20 keV at dosage from 1*10¹⁵ to 5*10¹⁵ ions/cm².

As shown in FIGS. 3C and 3D, with the gate electrode 330 serving as a mask, an N-type dopant is implanted into the semiconductor layer 310 by two ion implantations, respectively, to form N-type lightly doped regions partially overlapping the source/drain 340/350 regions. Two N-type LDDs 360 and 361 are formed in the vicinity of the gate insulator layer 320. The ion implantations are performed at energy from 50 to 110 keV at dosage from 5*10¹² to 1*10¹⁴ ions/cm². The N-type dopant is implanted into the semiconductor layer 310 at angle II and angle I deviating from a normal line of the substrate 302 by between 0 and 30°, respectively. The N-type dopant may comprise As, P, AsHₓ, or PHₓ.

As shown in FIG. 3E, an interlayer dielectric layer 370 is formed on the gate electrode 330 and the surface of the substrate 302. A conductive line 380 is formed in the interlayer dielectric layer 370, contacting the source/drain 340/350 regions.

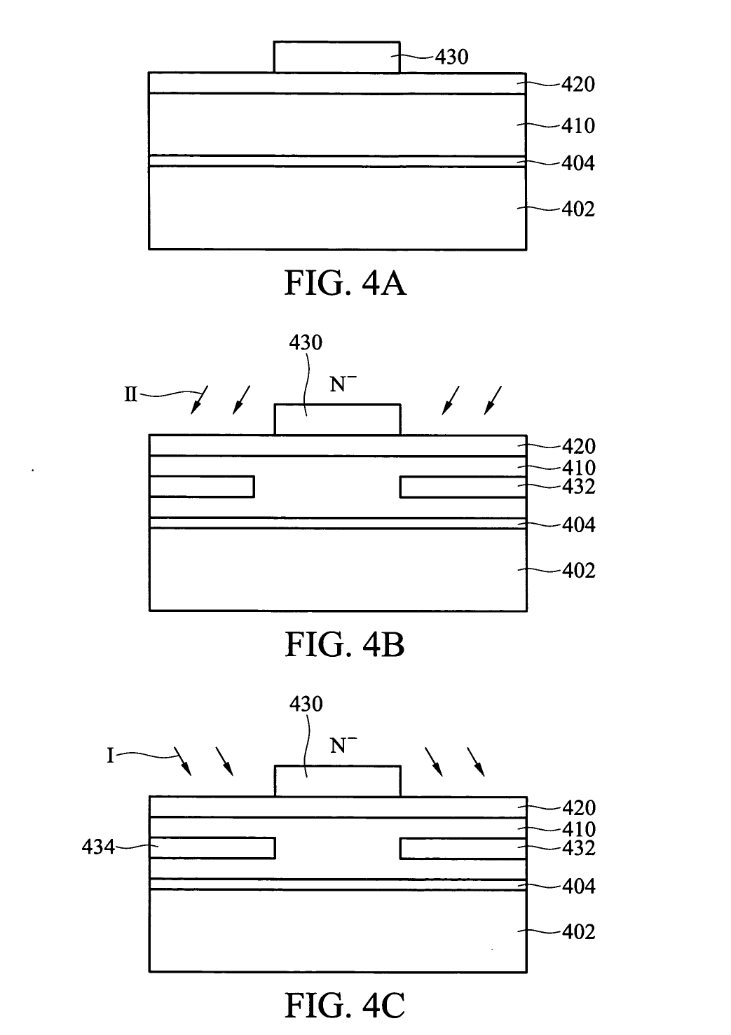

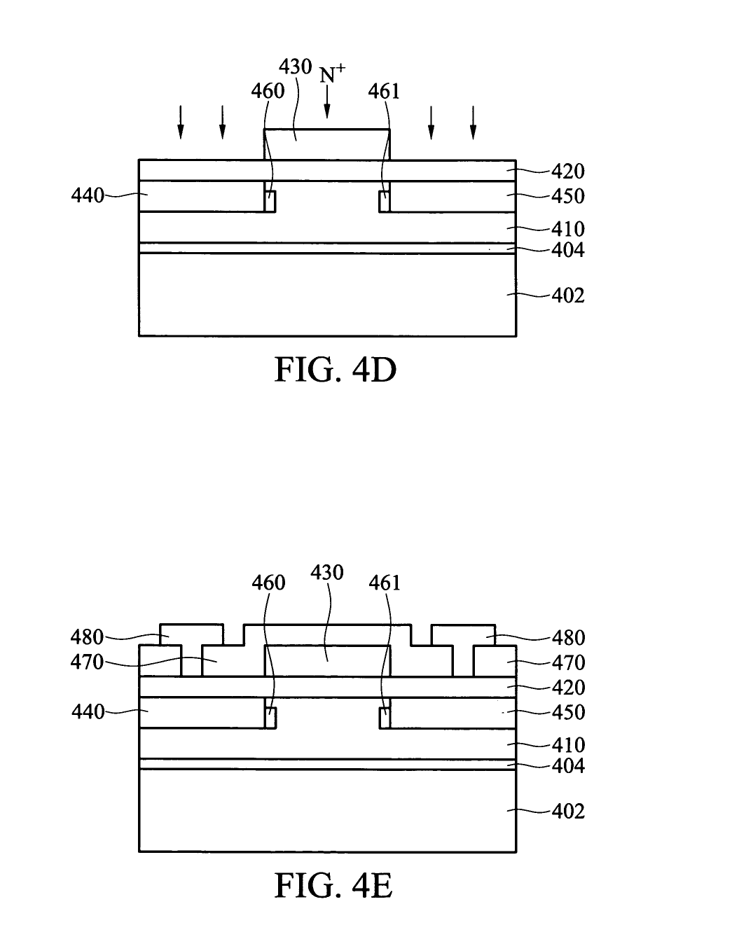

FIGS. 4A to 4E are cross-sectional views of a method of fabricating a liquid crystal display device according to an embodiment of the present invention. The method comprises the following steps.

As shown in FIG. 4A, a substrate 402 is provided followed by formation of a buffer layer 404 on the surface thereof. A semiconductor layer 410 is formed on the buffer layer 404 and a gate insulator layer 420 is formed on the semiconductor layer 410. Subsequently, a gate electrode 430 is formed on the gate insulator layer 420.

As shown in FIGS. 4B and 4C, with the gate electrode 430 serving as a mask, an N-type dopant is implanted into the semiconductor layer 410 by two ion implantations, respectively, to form N-type lightly doped regions 432 and 434. The ion implantations are performed at energy from 50 to 110 keV at dosage from 5*10¹² to 1*10¹⁴ ions/cm². The N-type dopant is implanted into the semiconductor layer 410 at angle II and angle I deviating from a normal line of the substrate 402 by between 0 and 30°, respectively. The N-type dopant may comprise As, P, AsHₓ, or PHₓ.

As shown in FIG. 4D, with the gate electrode 430 serving as a mask, an N-type dopant is implanted into the semiconductor layer 410 by an ion implantation, forming source/drain 440/450 regions partially overlapping the N-type lightly doped regions 432 and 434. Two N-type LDDs 460 and 461 are formed in the vicinity of the gate insulator layer 420. The N-type dopant may comprise As, P, AsHₓ, or PHₓ. The N-type dopant is implanted into the semiconductor layer 410 substantially perpendicular to the surface of the substrate 402 at energy from 10 to 20 keV at dosage from 1*10¹⁵ to 5*10¹⁵ ions/cm².

As shown in FIG. 4E, an interlayer dielectric layer 470 is formed on the gate electrode 430 and the surface of the substrate 402. A conductive line 480 is formed in the interlayer dielectric layer 470, contacting the source/drain 440/450 regions.

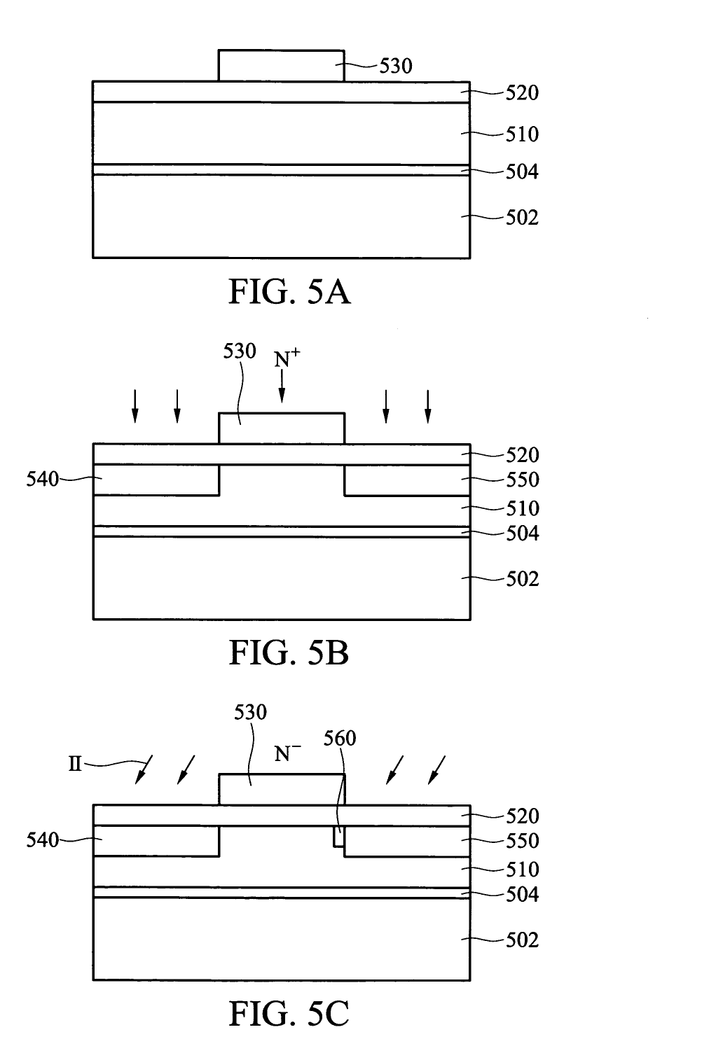

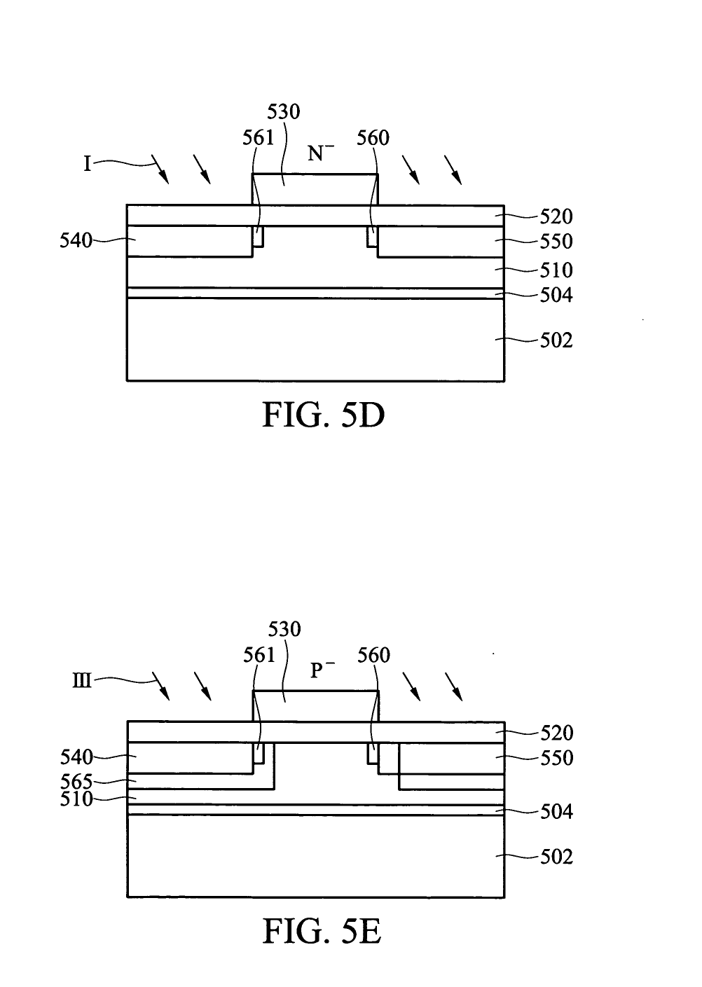

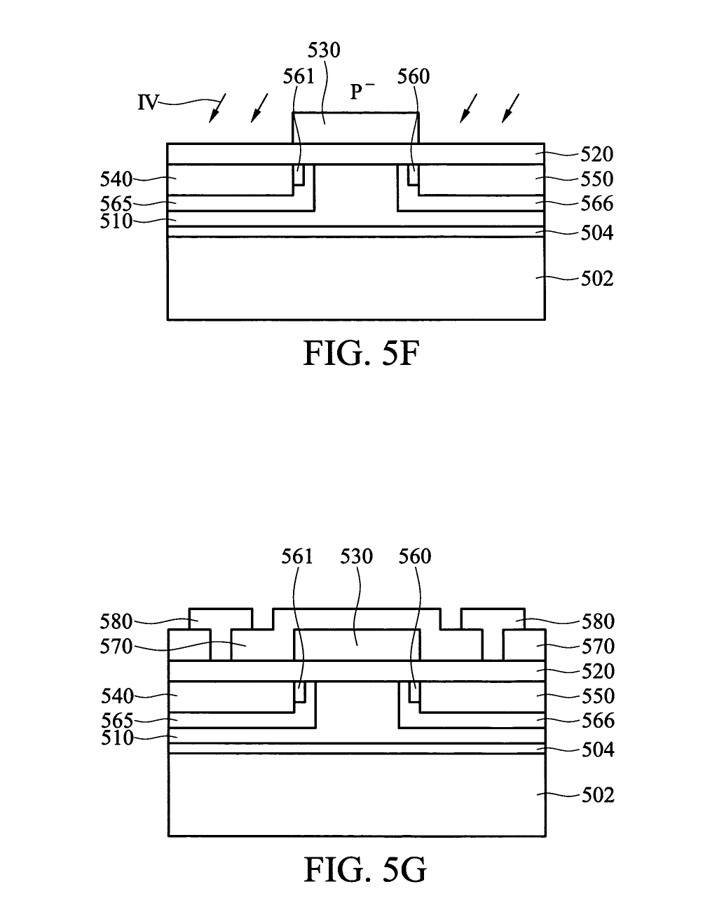

As shown in FIG. 5 through 8, methods of fabricating P-type LDDs surrounding source/drain electrodes are provided to diminish the depletion area between source/drain electrodes, and to solve problems such as leakage current and punch-through effect.

FIGS. 5A to 5G are cross-sectional views of a method of fabricating a liquid crystal display device according to an embodiment of the present invention. The method comprises the following steps.

As shown in FIG. 5A, a substrate 502 is provided followed by formation of a buffer layer 504 on the surface thereof. A semiconductor layer 510 is formed on the buffer layer 504 and a gate insulator layer 520 is formed on the semiconductor layer 510. Subsequently, a gate electrode 530 is formed on the gate insulator layer 520.

As shown In FIG. 5B, with the gate electrode 530 serving as a mask, an N-type dopant is implanted into the semiconductor layer 510 by an ion implantation, forming source/drain 540/550 regions. The N-type dopant may comprise As, P, AsHₓ, or PHₓ. The N-type dopant is implanted into the semiconductor layer 510 substantially perpendicular to the surface of the substrate 502 at energy from 10 to 20 keV at dosage from 1*10¹⁵ to 5*10¹⁵ ions/cm².

As shown in FIGS. 5C and 5D, with the gate electrode 530 serving as a mask, an N-type dopant is implanted into the semiconductor layer 510 by two ion implantations, respectively, to form N-type lightly doped regions partially overlapping the source/drain 540/550 regions. Two N-type LDDs 560 and 561 are formed below the gate insulator layer 520. The ion implantations are performed at energy from 10 to 50 keV at dosage from 5*10¹² to 1*10¹⁴ ions/cm². The N-type dopant is implanted into the semiconductor layer 510 at angle II and angle I deviating from a normal line of the substrate 502 by between 40 and 80°, respectively. The N-type dopant may comprise As, P, AsHₓ, or PHₓ.

As shown in FIGS. 5E and 5F, with the gate electrode 530 serving as a mask, two ion implantations implant a P-type dopant into the semiconductor layer 510, respectively, to form P-type lightly doped regions surrounding the source/drain 540/550 regions and the N-type LDDs 560 and 561. Two P-type LDDs 565 and 566 are formed. The ion implantations are performed at energy from 40 to 80 keV at dosage from 5*10¹¹ to 2*10¹² ions/cm². The P-type dopant is implanted into the semiconductor layer 510 at angle III and angle IV deviating from a normal line of the substrate 502 by between 40 and 60°, respectively. The P-type dopant may comprise B, BHₓ, or BFₓ.

As shown in FIG. 5G, an interlayer dielectric layer 570 is formed on the gate electrode 530 and the surface of the substrate 502. A conductive line 580 is formed in the interlayer dielectric layer 570, contacting the source/drain 540/550 regions.

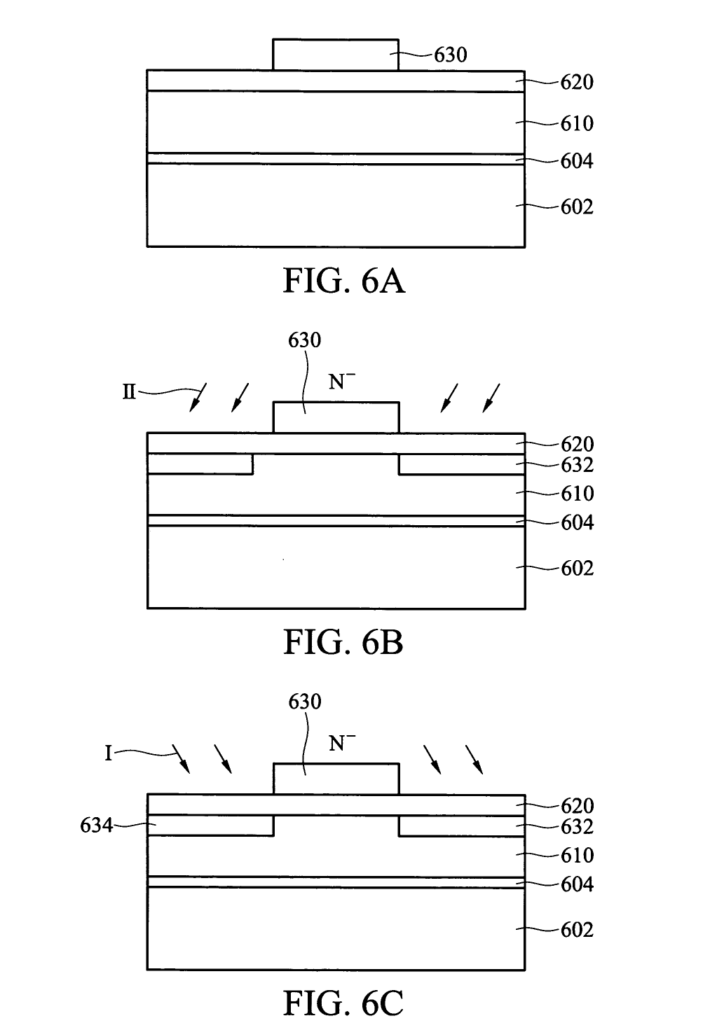

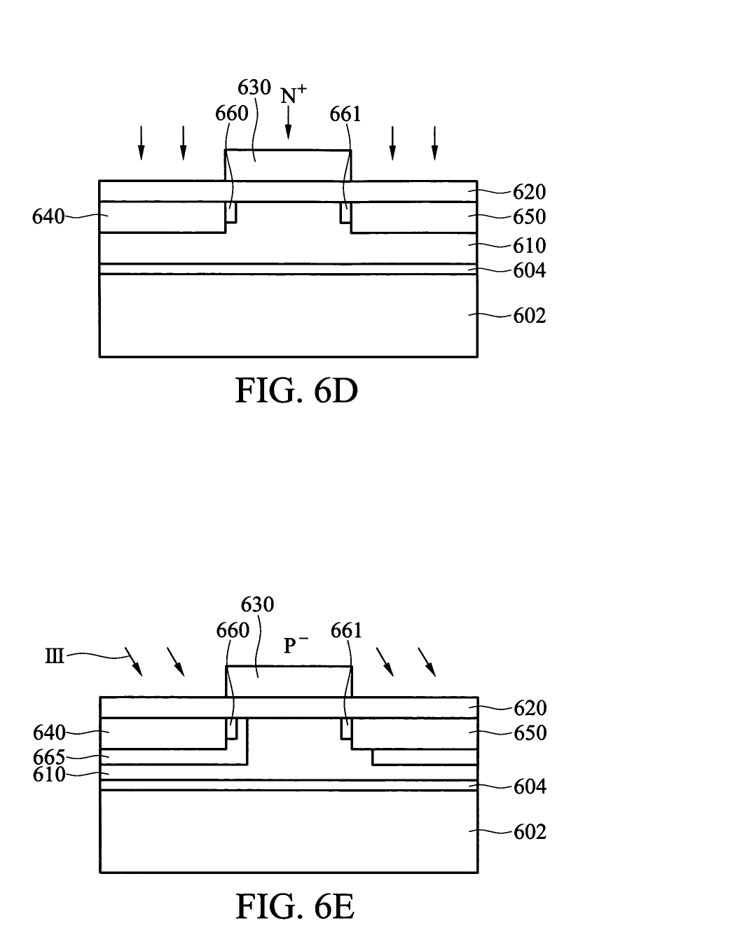

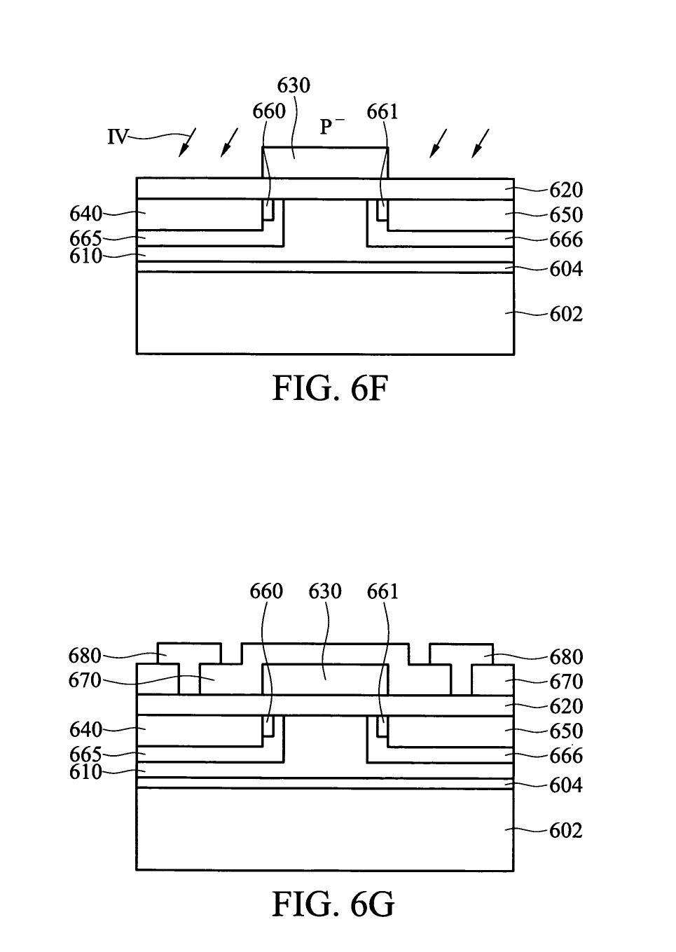

FIGS. 6A to 6G are cross-sectional views of a method of fabricating a liquid crystal display device according to an embodiment of the present invention. The method comprises the following steps.

As shown in FIG. 6A, a substrate 602 is provided followed by formation of a buffer layer 604 on the surface thereof. A semiconductor layer 610 is formed on the buffer layer 604 and a gate insulator layer 620 is formed on the semiconductor layer 610. Subsequently, a gate electrode 630 is formed on the gate insulator layer 620.

As shown in FIGS. 6B and 6C, with the gate electrode 630 serving as a mask, an N-type dopant is implanted into the semiconductor layer 610 by two ion implantations, respectively, to form N-type lightly doped regions 632 and 634. The ion implantations are performed at energy from 10 to 50 keV at dosage from 5*10¹² to 1*10¹⁴ ions/cm². The N-type dopant is implanted into the semiconductor layer 610 at angle II and angle I deviating from a normal line of the substrate 602 by between 40 and 80°, respectively. The N-type dopants may comprise As, P, AsHₓ, or PHₓ.

As shown in FIG. 6D, with the gate electrode 630 serving as a mask, an N-type dopant is implanted into the semiconductor layer 610 by an ion implantation, forming source/drain 640/650 regions partially overlapping the N-type lightly doped regions 632 and 634. Two N-type LDDs 660 and 661 are formed below the gate insulator layer 620. The N-type dopant may comprise As, P, AsHₓ, or PHₓ. The N-type dopant is implanted into the semiconductor layer 610 substantially perpendicular to the surface of the substrate 602 at energy from 10 to 20 keV at dosage from 1*10¹⁵ to 5*10¹⁵ ions/cm².

As shown in FIGS. 6E and 6F, with the gate electrode 630 serving as a mask, an P-type dopant is implanted into the semiconductor layer 610 by two ion implantations, respectively, to form P-type lightly doped regions surrounding the source/drain 640/650 regions and the N-type LDDs 660 and 661. Two P-type LDDs 665 and 666 are formed. The ion implantations are performed at energy from 40 to 80 keV at dosage from 5*10¹¹ to 2*10¹² ions/cm². The P-type dopant is implanted into the semiconductor layer 610 at angle III and angle IV deviating from a normal line of the substrate 602 by between 40 and 60°, respectively. The P-type dopant may comprise B, BHₓ, or BFₓ.

As shown in FIG. 6G, an interlayer dielectric layer 670 is formed on the gate electrode 630 and the surface of the substrate 602. A conductive line 680 is formed in the interlayer dielectric layer 670, contacting the source/drain 640/650 regions.

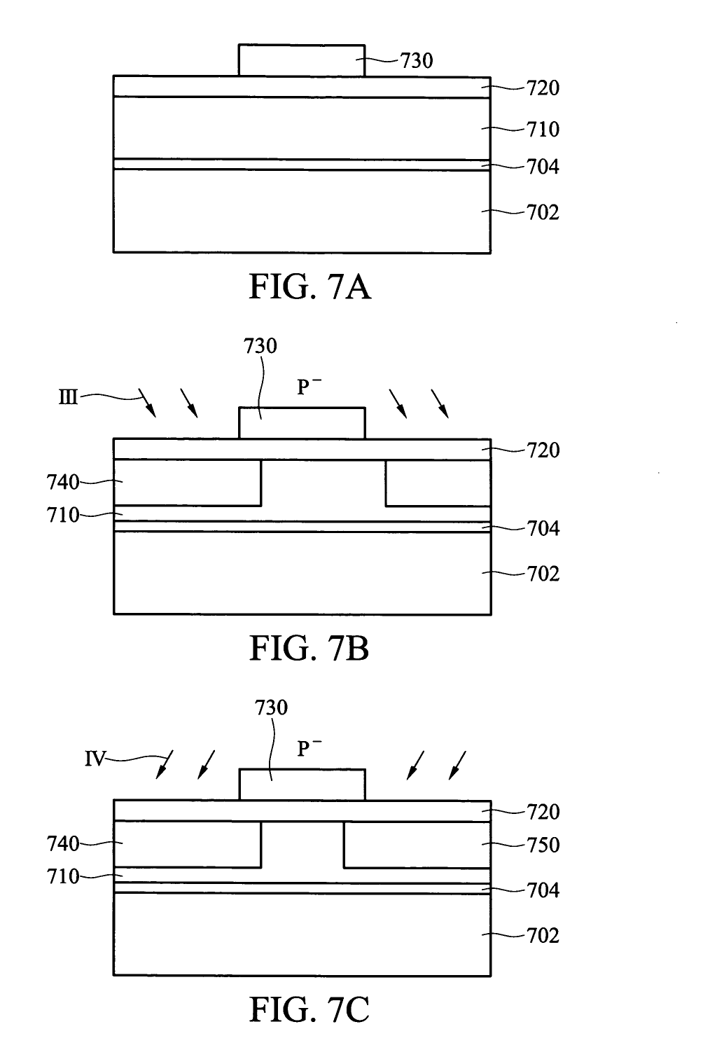

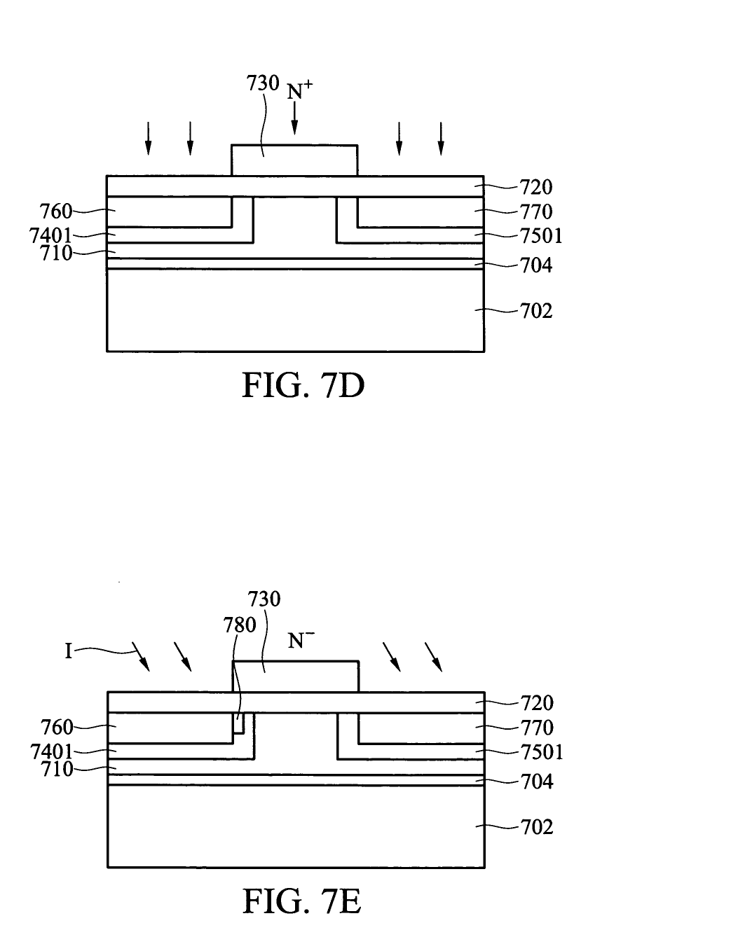

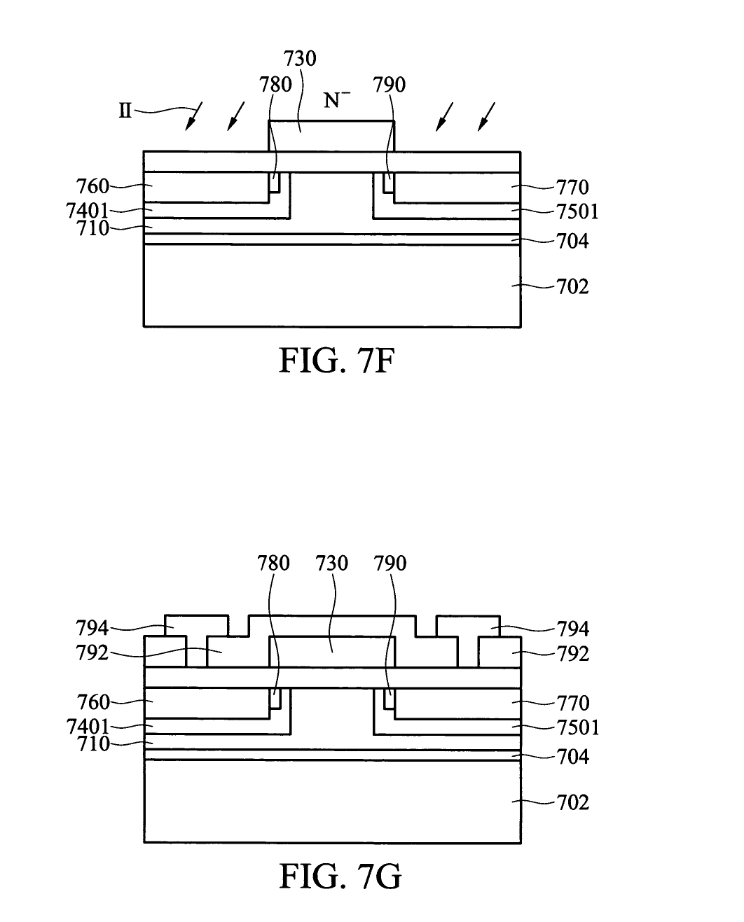

FIGS. 7A to 7G are cross-sectional views of a method of fabricating a liquid crystal display device according to an embodiment of the present invention. The method comprises the following steps.

As shown in FIG. 7A, a substrate 702 is provided followed by formation of a buffer layer 704 on the surface thereof. A semiconductor layer 710 is formed on the buffer layer 704 and a gate insulator layer 720 is formed on the semiconductor layer 710. Subsequently, a gate electrode 730 is formed on the gate insulator layer 720.

As shown in FIGS. 7B and 7C, with the gate electrode 730 serving as a mask, an P-type dopant is implanted into the semiconductor layer 710 by two ion implantations, respectively, to form P-type lightly doped regions 740/750. The ion implantations are performed at energy from 40 to 80 keV at dosage from 5*10¹¹ to 2*10^{12 ions/cm}². The P-type dopant is implanted into the semiconductor layer 710 at angle III and angle IV deviating from a normal line of the substrate 702 by between 40 and 60°, respectively. The P-type dopant may comprise B, BHₓ, or BFₓ.

As shown in FIG. 7D, with the gate electrode 730 serving as a mask, an N-type dopant is implanted into the semiconductor layer 710 by an ion implantation, forming source/drain 760/770 regions partially overlapping the P-type lightly doped regions 740/750, respectively. At the meantime, P-type LDDs 7401/7501 are formed. The N-type dopant may comprise As, P, AsHₓ, or PHₓ. The N-type dopant is implanted into the semiconductor layer 710 substantially perpendicular to the surface of the substrate 702 at energy from 10 to 20 keV at dosage from 1*10¹⁵ to 5*10¹⁵ ions/cm².

As shown in FIGS. 7E and 7F, with the gate electrode 730 serving as a mask, an N-type dopant is implanted into the semiconductor layer 710 by two ion implantations, respectively, to form N-type lightly doped regions partially overlapping the P-type lightly doped regions 740/750 and the source/drain 760/770 regions, respectively. Two N-type LDDs 780 and 790 are formed just below the gate insulator layer 720. The ion implantations are performed at energy from 10 to 50 keV at dosage from 5*10¹² to 1*10¹⁴ ions/cm². The N-type dopant is implanted into the semiconductor layer 710 at angle I and angle II deviating from a normal line of the substrate 702 by between 40 and 80°, respectively. The N-type dopant may comprise As, P, AsHₓ, or PHₓ.

As shown in FIG. 7G, an interlayer dielectric layer 792 is formed on the gate electrode 730 and the surface of the substrate 702. A conductive line 794 is formed in the interlayer dielectric layer 792, contacting the source/drain 760/770 regions.

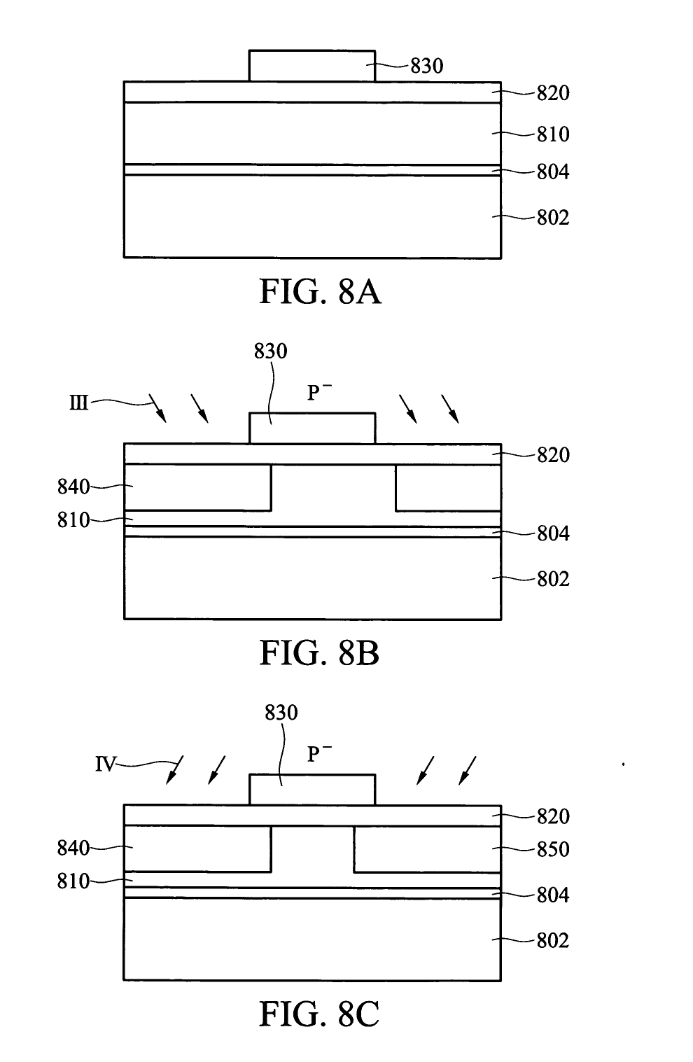

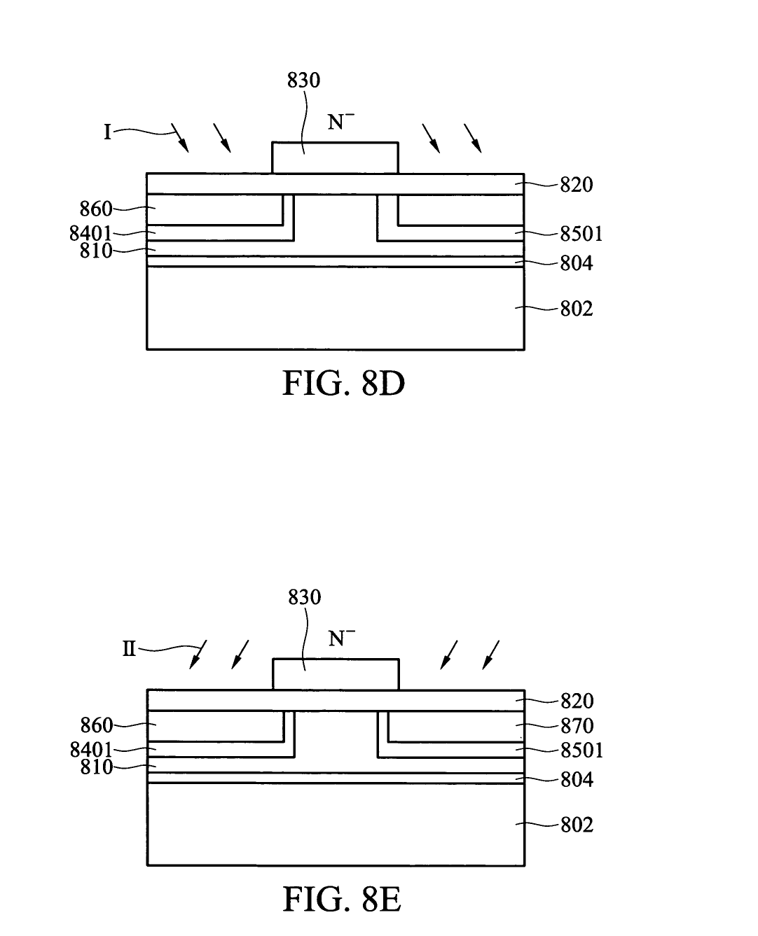

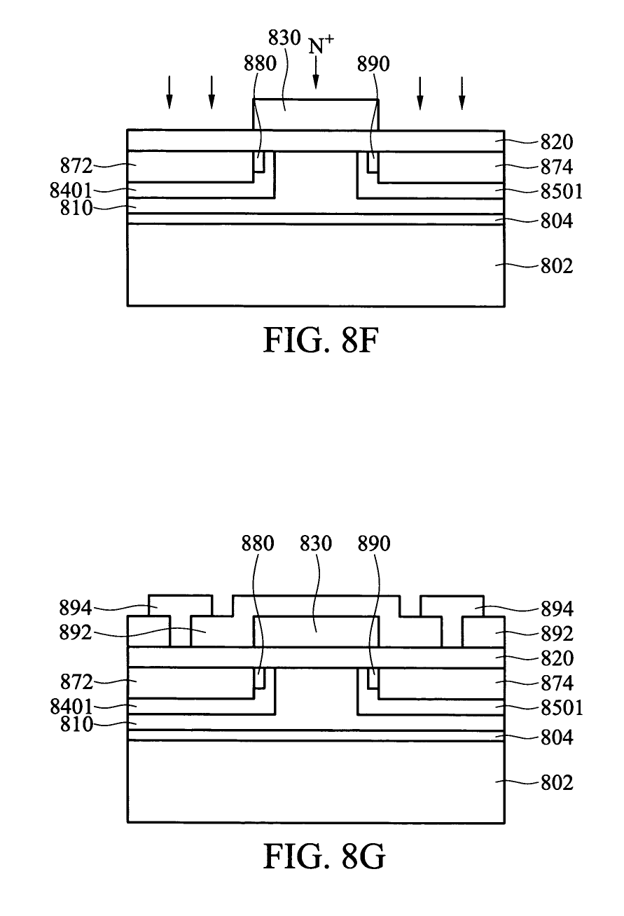

FIGS. 8A to 8G are cross-sectional views of a method of fabricating a liquid crystal display device according to an embodiment of the present invention. The method comprises the following steps.

As shown in FIG. 8A, a substrate 802 is provided followed by formation of a buffer layer 804 on the surface thereof. A semiconductor layer 810 is formed on the buffer layer 804 and a gate insulator layer 820 is formed on the semiconductor layer 810. Subsequently, a gate electrode 830 is formed on the gate insulator layer 820.

As shown in FIGS. 8B and 8C, with the gate electrode 830 serving as a mask, an P-type dopant is implanted into the semiconductor layer 810 by two ion implantations, respectively, to form P-type lightly doped regions 840/850. The ion implantations are performed at energy from 40 to 80 keV at dosage from 5*10¹¹ to 2*10¹² ions/cm². The P-type dopant is implanted into the semiconductor layer 810 at angle III and angle IV deviating from a normal line of the substrate 802 by between 40 and 60°, respectively. The P-type dopant may comprise B, BHₓ, or BFₓ.

As shown in FIGS. 8D and 8E, with the gate electrode 830 serving as a mask, an N-type dopant is implanted into the semiconductor layer 810 by two ion implantations, respectively, to form N-type lightly doped regions 860 and 870 partially overlapping the P-type lightly doped regions 840 and 850. Two P-type LDDs 8401/8501 are formed. The ion implantations are performed at energy from 10 to 50 keV at dosage from 5*10¹² to 1*10¹⁴ ions/cm². The N-type dopant is implanted into the semiconductor layer 810 at angle I and angle II deviating from a normal line of the substrate 802 by between 40 and 80°, respectively. The N-type dopants may comprise As, P, AsHₓ, or PHₓ.

As shown in FIG. 8F, with the gate electrode 830 serving as a mask, an N-type dopant is implanted into the semiconductor layer 810 by an ion implantation, forming source/drain 872/874 regions partially overlapping the P-type lightly doped regions 840/850 and the N-type lightly doped regions 860/870. Two N-type LDDs 880 and 890 are formed just below the gate insulator layer 820. The N-type dopant may comprise As, P, AsHₓ, or PHₓ. The N-type dopant is implanted into the semiconductor layer 810 substantially perpendicular to the surface of the substrate 802 at energy from 10 to 20 keV at dosage from 1*10¹⁵ to 5*10¹⁵ ions/cm².

As shown in FIG. 8G, an interlayer dielectric layer 892 is formed on the gate electrode 830 and the surface of the substrate 802. A conductive line 894 is formed in the interlayer dielectric layer 892, contacting the source/drain 872/874 regions.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of fabricating a liquid crystal display device, comprising:
providing a substrate;
forming a buffer layer on the substrate;
forming a semiconductor layer on the buffer layer;
forming a gate insulator layer on the semiconductor layer;
forming a gate electrode on the gate insulator layer;
implanting a first dopant into the semiconductor layer with the gate electrode serving as a mask to form source/drain regions;
implanting a second dopant into the semiconductor layer with the gate electrode serving as a mask to form a first lightly doped region, wherein the second dopant is implanted into the semiconductor layer at an angle between 0 and 80°, deviating from a normal line of the substrate; and
implanting a third dopant into the semiconductor layer with the gate electrode serving as a mask to form a second lightly doped region, wherein the third dopant is implanted into the semiconductor layer at an angle between 0 and 80°, deviating from a normal line of the substrate.

2. The method as claimed in claim 1, further comprising:
implanting a fourth dopant into the semiconductor layer with the gate electrode serving as a mask to form a third lightly doped region, wherein the third lightly doped region surrounds the first lightly doped region and one of the source/drain regions.
implanting a fifth dopant into the semiconductor layer with the gate electrode serving as a mask to form a fourth lightly doped region, wherein the fourth lightly doped region surrounds the second lightly doped region and one of the source/drain regions.

3. The method as claimed in claim 1, wherein the source/drain regions partially overlap the first lightly doped region and the second lightly doped region, respectively.

4. The method as claimed in claim 1, wherein the first dopant is implanted into the semiconductor layer substantially perpendicular to a surface of the substrate.

5. The method as claimed in claim 1, wherein the first dopant, the second dopant, and the third dopant are implanted into the semiconductor layer by ion implantations.

6. The method as claimed in claim 2, wherein the fourth dopant and the fifth dopant are implanted into the semiconductor layer by ion implantations.

7. The method as claimed in claim 1, wherein the first dopant, the second dopant, and the third dopant are As, P, AsHₓ, or PHₓ.

8. The method as claimed in claim 2, wherein the fourth dopant and the fifth dopant are B, BHₓ, or BFₓ.

9. The method as claimed in claim 1, wherein the first dopant, the second dopant, and the third dopant are implanted into the semiconductor layer at energy from 10 to 20 keV, 10 to 50 keV, and 10 to 50 keV, respectively.

10. The method as claimed in claim 2, wherein the fourth dopant and the fifth dopant are implanted into the semiconductor layer at energy from 40 to 80 keV, respectively.

11. The method as claimed in claim 1, wherein the first dopant, the second dopant, and the third dopant are implanted into the semiconductor layer at dosage from 1*10¹⁵ to 5*10¹⁵ ions/cm², 5*10¹² to 1*10¹⁴ ions/cm², and 5*10¹² to 1*10¹⁴ ions/cm², respectively.

12. The method as claimed in claim 2, wherein the fourth dopant and the fifth dopant are implanted into the semiconductor layer at dosage from 5*10¹¹ to 2*10¹² ions/cm², respectively.

13. The method as claimed in claim 2, wherein the fourth dopant and the fifth dopant are implanted into the semiconductor layer at an angle between 40 and 60°, deviating from a normal line of the substrate, respectively.

14. The method as claimed in claim 1, further comprising:
forming an interlayer dielectric layer covering the gate electrode and the surface of the substrate; and
forming a conductive line in the interlayer dielectric layer, contacting the source/drain regions.
